(19) United States
(12) Patent Application Publication
(10) Pub. No.: US 2005/0052568 A1
(43) Pub. Date: Mar. 10, 2005

(54) Digital image capturing module assembly and method of fabricating the same

(75) Inventors: Kah-Ong Tan, Shanghai (CN); Hui Wang, Shanghai (CN); Dong-Jin Zhang, Shanghai (CN); Peter Tao, Shanghai (CN)

Correspondence Address: Mr. Peter F. Corless;EDWARDS & ANGELL, LLP, 101 Federal Street, Boston, MA, 02110, US

(73) Assignee: Inventec Micro-Electronics Corporation

(21) Appl. No.: 10/660,092

(22) Filed: Sep. 10, 2003

(51) Int. Cl. H04N 5/225; H01L 27/00

(52) U.S. Cl. 348/374; 250/208.1; 348/340

(57) ABSTRACT

A digital image capturing module assembly and method of fabricating the same is proposed, which is used for the assembly of a digital image capturing module from a photosensitive printed circuit board and a lens holder. The proposed assembly method is characterized by the provision of a ring plane between focusing plane and corner-located aligning posts on the lens holder so as to allow the coated adhesive layer over the ring plane to provide a sealed light impenetrable effect at the junction between the photosensitive printed circuit board and the lens holder. This feature allows the captured image by the digital image capturing module to be substantially free of sidelight effect and thus more assured in picture quality. Moreover, it can simplify the assembly process to help increase the yield of the fabrication of digital image capturing modules.

### BACKGROUND OF THE INVENTION

1. Field of the Invention

This invention relates to electronics assembly technology, and more particularly, to a digital image capturing module assembly and method of fabricating the same, which is designed for use to assemble a digital image capturing module by mounting a photosensitive printed circuit board (PCB), such as a CCD (Charge Coupled Device) based or a CMOS (Complementary Metal Oxide Semiconductor) based circuit board, on a lens holder.

2. Description of Related Art

Digital image capturing module is a key component in the assembly of a digital still camera (DSC) or a camera-equipped electronic device such as mobile phone, which is composed of a lens holder and a photosensitive printed circuit board (PCB), where the lens holder is used to hold a lens unit that is used to capture an optical image and focus the captured image on a focusing plane on the rear side of the lens holder, while the photosensitive printed circuit board is, for example, a CCD (Charge Coupled Device) based or a CMOS (Complementary Metal Oxide Semiconductor) based circuit board, and which is positioned on the focusing plane of the lens holder for the purpose of converting the optical image focused thereon into digital form.

A conventional method for the assembly of a digital image capturing module from a lens holder and a photosensitive printed circuit board is to use an adhesive agent to adhere the photosensitive printed circuit board onto the periphery of the focusing plane of the lens holder. After the adhesive agent is cured, it can firmly secure the photosensitive printed circuit board in position on the lens holder as well as provide a sealed light-impenetrable effect at the junction between the photosensitive printed circuit board and the lens holder to prevent undesired sidelight from penetrating to the inside of the digital image capturing module that would otherwise degrade the quality of the captured image.

One drawback to the foregoing assembly method, however, is that the coating of the adhesive layer to the lens holder should be conducted in two passes, wherein the first pass is used to coat the adhesive agent crosswise while the second pass is used to coat the adhesive agent lengthwise. As the coating process is completed, however, uncoated blank spots would exist at the corners of the periphery of the focusing plane. If these uncoated blank spots are unsealed, they would become light-penetrable holes in the adhesive layer, which would allow sidelight to pass therethrough to the inside of the lens holder and thus degrade the picture quality of the captured image by the digital image capturing module. One solution to this problem is to use labor force to manually fill up these uncoated blank spots in a subsequent procedural step. One drawback to this solution, however, is that it would make the overall fabrication process more laborious and time-timing, thus desirably resulting in a low yield to the fabrication of the digital image capturing modules.

### SUMMARY OF THE INVENTION

It is therefore an objective of this invention to provide a new digital image capturing module assembly and method of fabricating the same which can provide a sealed light-impenetrable effect at the junction between the photosensitive printed circuit board and the lens holder in spite of the fact that there exists uncoated blank spots at the corners of the periphery of the focusing plane on the lens holder.

It is another objective of this invention to provide a new digital image capturing module assembly and method of fabricating the same which can help simplify the assembly process and reduce the required assembly time so as to allow the assembly of digital image capturing modules to be increased in yield.

The digital image capturing module assembly and method of fabricating the same according to the invention is designed for use to assemble a digital image capturing module by mounting an photosensitive printed circuit board, such as a CCD (Charge Coupled Device) based or a CMOS (Complementary Metal Oxide Semiconductor) based circuit board, to a lens holder.

The digital image capturing module assembly and method of fabricating the same according to the invention is characterized by the provision of a ring plane between the focusing plane and the corner-located aligning posts on the lens holder so as to allow the part of the adhesive layer coated on the ring plane to completely surround the focusing plane and therefore provide a sealed light impenetrable effect at the junction between the photosensitive printed circuit board and the lens holder in spite of the fact that there exists uncoated blank spots beside the corner-located aligning posts. This feature allows the captured image by the digital image capturing module to be substantially free of sidelight effect and thus more assured in picture quality. Moreover, the invention can simplify the assembly process since it would be unnecessary to fill up the uncoated blank spots by labor force, which can help increase the yield of the fabrication of digital image capturing modules.

### BRIEF DESCRIPTION OF DRAWINGS

The invention can be more fully understood by reading the following detailed description of the preferred embodiments, with reference made to the accompanying drawings, wherein:

FIG. 1 is a schematic diagram showing an exploded perspective view of the various constituent parts used to assemble a digital image capturing module assembly according to the invention;

FIG. 2 is a schematic diagram showing a sectional view of the exploded digital image capturing module assembly shown in FIG. 1;

FIG. 3 is a schematic diagram showing a plan view of the rear side of a lens holder utilized in the digital image capturing module assembly according to the invention;

FIG. 4 is a schematic sectional diagram used to depict a heating process during the fabrication of the digital image capturing module assembly according to the invention; and

FIG. 5 is a schematic diagram showing a sectional view of the finished product of the digital image capturing module assembly according to the invention.

### DETAILED DESCRIPTION OF PREFERRED EMBODIMENTS

The digital image capturing module assembly and method of fabricating the same according to the invention is disclosed in full details by way of preferred embodiments in the following with reference to the accompanying drawings.

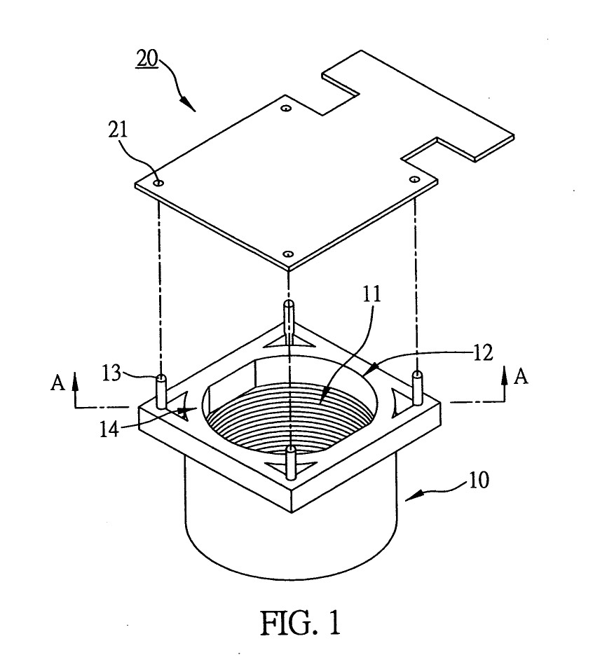

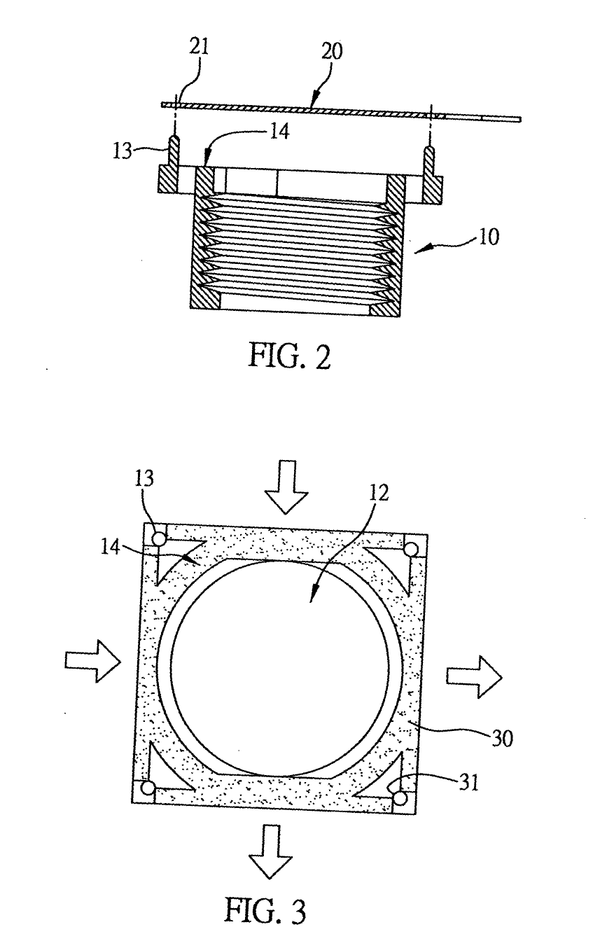

Referring first to FIG. 1 and FIG. 2, the initial steps in the fabrication of a digital image capturing module assembly according to the invention is to prepare a lens holder 10 and a photosensitive printed circuit board 20.

The lens holder 10 has an inside hollowed portion 11 for the accommodation of a lens unit (not shown) therein, and the lens unit is to be used to capture an optimal image and focus the captured image on a focusing plane 12 on the rear side of the lens holder 10. Further, the lens holder 10 is formed with a plurality of aligning posts, for example 4 aligning posts 13, on the periphery of the focusing plane 12. These aligning posts 13 are made of a thermally-meltable material, such as plastics, that can be melted when subjected to heat. Moreover, the aligning posts 13 should be each greater in length than the thickness of the photosensitive printed circuit board 20. A characteristic feature of the invention is that the lens holder 10 is formed with a ring plane 14 between the focusing plane 12 and the aligning posts 13 that completely surrounds the focusing plane 12.

The photosensitive printed circuit board 20 is, for example, a CCD (Charge Coupled Device) based or a CMOS (Complementary Metal Oxide Semiconductor) based circuit board, and which is to be used to convert the optical image captured by the lens unit (not shown) in the lens holder 10 into digital form. The photosensitive printed circuit board 20 is formed with a plurality of aligning holes 21 on the periphery thereof, whose size and position are correspondingly mapped to the aligning posts 13 on the lens holder 10.

Referring next to FIG. 3, during the assembly process, the first step is to perform a coating process to coat an adhesive agent over the periphery of the focusing plane 12 as well as over the ring plane 14 to form an adhesive layer 30 thereon. This coating process is conducted in two passes, wherein the first pass is used to coat the adhesive agent in the crosswise direction while the second pass is used to coat the adhesive agent in the lengthwise direction, as respectively indicated by the arrows in FIG. 3. As the coating process is completed, it can be seen from the illustration of FIG. 3 that uncoated blank spots 31 would exist beside the aligning posts 13 at the corners of the periphery of the focusing plane 12 since these aligning posts 13 would hinder the coating of the adhesive agent over these areas. However, owing to the provision of the ring plane 14, the coated adhesive layer 30 would nonetheless completely surround the focusing plane 12. In other words, although the uncoated blank spots 31 beside the corner-located aligning posts 13 would be light-penetrable holes, the part of the adhesive layer 30 that is coated over the ring plane 14 would nonetheless completely surround the focusing plane 12 to server as a light-impenetrable shield to inside of the lens holder 10.

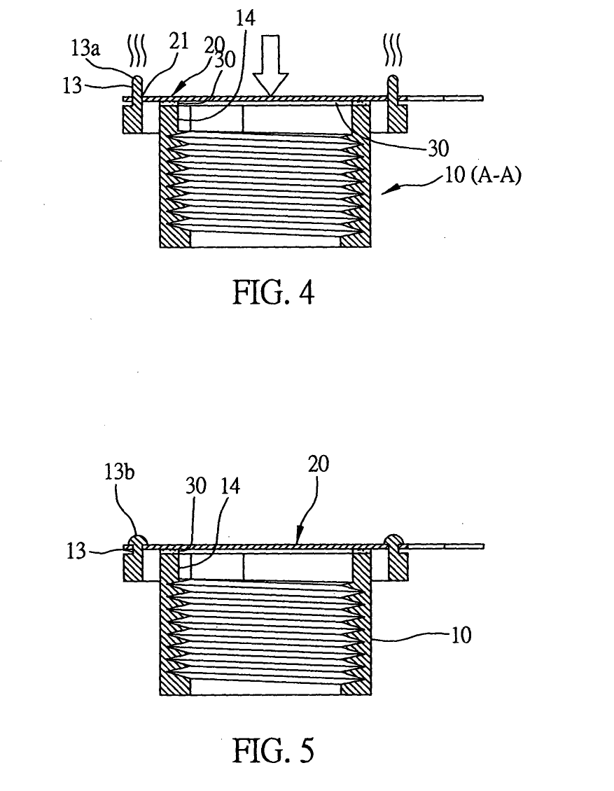

Referring further to FIG. 4, in the next step, a mounting process is performed to mount the photosensitive printed circuit board 20 onto the lens holder 10 by fitting the aligning holes 21 in the photosensitive printed circuit board 20 to the aligning posts 13 on the lens holder 10. Since the aligning posts 13 are each greater in length than the thickness of the photosensitive printed circuit board 20, the respective tips 13a of the aligning posts 13 will be protruding over the photosensitive printed circuit board 20. Next, with a pressing force (as indicated by the arrow in FIG. 4) being applied against the photosensitive printed circuit board 10, a heating process is performed to apply heat against the protruding tips 13a of the aligning posts 13 so as to melt down the protruding tips 13a of the aligning posts 13.

Referring further to FIG. 5, after the protruding tips 13a of the aligning posts 13 have been melted and cured, they are each transformed into a bolting structure 13b which can help firmly secure the photosensitive printed circuit board 20 in position on the lens holder 10. Moreover, since the firmly-secured photosensitive printed circuit board 20 can forcefully press against the underlying adhesive layer 30, it allows the adhesive layer 30 to firmly adhere the photosensitive printed circuit board 20 in position on the lens holder 10 as well as provide a sealed light-impenetrable effect at the junction between the photosensitive printed circuit board 20 and the lens holder 10 so that no sidelight can pass therethrough to the inside of the lens holder 10. This completes the assembly of the digital image capturing module assembly according to the invention.

In practical application, since the adhesive layer 30 coated over the ring plane 14 completely surrounds the focusing plane 12, it can provide a sealed light-impenetrable effect at the junction between the photosensitive printed circuit board 20 and the lens holder 10 in spite of the fact that there exists uncoated blank spots 31 beside the corner-located aligning posts 13. This sealed light-impenetrable effect allows the captured image by the digital image capturing module to be substantially free of sidelight and thus more assured in picture quality.

In conclusion, the invention provides a digital image capturing module assembly and method of fabricating the same for use to assemble a digital image capturing module from a photosensitive printed circuit board and a lens holder, and which is characterized by the provision of a ring plane between the focusing plane and the corner-located aligning posts on the lens holder so as to allow the part of the adhesive layer coated on the ring plane to completely surround the focusing plane and therefore provide a sealed light impenetrable effect at the junction between the photosensitive printed circuit board and the lens holder in spite of the fact that there exists uncoated blank spots beside the corner-located aligning posts. This feature allows the captured image by the digital image capturing module to be substantially free of sidelight effect and thus more assured in picture quality. Moreover, the invention can simplify the assembly process since it would be unnecessary to fill up the uncoated blank spots by labor force, which can help increase the yield of the fabrication of digital image capturing modules. The invention is therefore more advantageous to use than the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A digital image capturing module assembly, which comprises:
a lens holder, which has one side defined as a focusing plane, and which is formed with a plurality of aligning posts on the periphery of the focusing plane and is further formed with a ring plane between the focusing plane and the aligning posts that completely surrounds the focusing plane;
an adhesive layer, which is coated over the periphery of the focusing plane and over the ring plane; and
a photosensitive printed circuit board, which is formed with a plurality of aligning holes corresponding to the aligning posts on the lens holder, and which is mounted on the lens holder by fitting the aligning holes thereof to the aligning posts on the lens holder;
wherein
the respective tips of the aligning posts on the lens holder are each melted into a bolting structure to secure the photosensitive printed circuit board firmly in position on the lens holder;
and wherein
the firmly-secured photosensitive printed circuit board forcefully presses against the adhesive layer to be thereby adhered firmly in position on the lens holder with the adhesive layer providing a sealed light-impenetrable effect at the junction between the photosensitive printed circuit board and the lens holder.

2. The digital image capturing module assembly of claim 1, wherein the photosensitive printed circuit board is a CCD-based photosensitive printed circuit board.

3. The digital image capturing module assembly of claim 1, wherein the photosensitive printed circuit board is a CMOS-based photosensitive printed circuit board.

4. The digital image capturing module assembly of claim 1, wherein the aligning posts on the lens holder are made of plastics.

5. A method for fabricating a digital image capturing module, comprising:
preparing a lens holder, which has one side defined as a focusing plane, and which is formed with a plurality of aligning posts on the periphery of the focusing plane and is further formed with a ring plane between the focusing plane and the aligning posts that completely surrounds the focusing plane;
preparing a photosensitive printed circuit board which is formed with a plurality of aligning holes corresponding to the aligning posts on the lens holder;
coating an adhesive layer over the periphery of the focusing plane and over the ring plane; and;
mounting the photosensitive printed circuit board in position on the lens holder by fitting the aligning holes in the photosensitive printed circuit board to the aligning posts on the lens holder; and
melting the respective tips of the aligning posts on the lens holder so as to transform the respective tips of the aligning posts into a bolting structure to secure the photosensitive printed circuit board in position on the lens holder as well as to allow the photosensitive printed circuit board to forcefully press against the adhesive layer to allow the photosensitive printed circuit board to be adhered firmly in position on the lens holder with the adhesive layer providing a sealed light-impenetrable effect at the junction between the photosensitive printed circuit board and the lens holder.

6. The method of claim 5, wherein the photosensitive printed circuit board is a CCD-based photosensitive printed circuit board.

7. The method of claim 5, wherein the photosensitive printed circuit board is a CMOS-based photosensitive printed circuit board.

8. The method of claim 5, wherein the aligning posts on the lens holder are made of plastics.
